(19) United States
(12) Patent Application Publication
(10) Pub. No.: US 2026/0367188 A1
(43) Pub. Date: Nov. 19, 2026

(54) METHOD FOR EVALUATING THE RELIABILITY OF A CONNECTION BETWEEN ELECTRICAL CONTACTS

(71) Applicant: SAFRAN ELECTRICAL & POWER, BLAGNAC (FR)

(72) Inventors: Ismaïl TCHAAOUAOU, MOISSY-CRAMAYEL (FR); Yves FARDEL, MOISSY-CRAMAYEL (FR)

(21) Appl. No.: 19/148,025

(22) PCT Filed: Jan. 31, 2024
(86) PCT No.: PCT/FR2024/050130

§ 371 Date: Jul. 15, 2025

(30) Foreign Application Priority Data
Feb. 6, 2023 (FR) FR2301103

(51) Int. Cl. G01R 31/69; G01N 3/06; G01N 3/34; G01N 3/56; G01R 31/00; H01R 13/622

(52) U.S. Cl. CPC G01R 31/69; G01N 3/066; G01N 3/34; G01N 3/56; G01R 31/006; H01R 13/622; G01N 2203/0005; G01N 2203/001; G01N 2203/0039; G01N 2203/0617; H01R 2201/26

(57) ABSTRACT

Method for evaluating the service life of an electrical connection between connectors each comprising at least one electrical contact housed in a casing, the casings being configured to be mechanically coupled to each other, comprising the following steps: measuring the change in the contact electrical resistance between the contacts alone, as a function of a number of movements of the electrical contacts against each other and for several movement amplitude values; determining, from the previous measurements, a function defining a maximum number of movements beyond which the electrical contact resistance exceeds a predefined maximum value representative of a degraded state of the connection, according to the amplitude of movement; and measuring movement amplitudes of each of the housings of the casings in which the electrical contacts are intended to be arranged, by subjecting the casings to mechanical stresses of different amplitude and frequency.

### DESCRIPTION

### Technical Field

The invention relates to the field of evaluating the service life, and therefore the reliability, of electrical connections between connectors subjected to mechanical stresses, in particular vibration stresses. The invention advantageously applies to the field of electrical connectors used in transport vehicles, in particular aerial, automotive or railway.

### Prior Art

“Fretting” is an oscillatory relative movement of low amplitude (from a few μm to a few tens of μm) that can be observed at the interface of two parts in quasi-static contact with each other, when these parts are subjected to vibrational stresses and/or relative movements. In most cases, this is a tangential movement of the parts against each other, and is generally a consequence of the vibrational stresses encountered by the system comprising these parts. For example, in the case of systems embedded in transport vehicles, in particular aircraft, these movements are caused by vibrations generated by vehicle engines.

Fretting is a phenomenon observed in many systems (electrical and/or mechanical), and is one of the main causes of damage to parts in contact. It causes a localized trace of wear of small dimensions, usually proportional to the contact surface of the parts and the amplitude of the movement generated between the parts.

An electrical connector consists of a casing with one or more housings in which one or more electrical contacts are located. The connectors are used in particular to connect two harnesses (clusters each consisting of one or more electrical cables surrounded by a protective sheath) together, or a harness with electrical equipment. When two connectors are coupled to each other, their electrical contacts make the electrical connection to each other. These electrical contacts are generally of the male/female type (or “pin/socket” in English), the plugging of the male contact into the female contact ensuring the electrical connection between them.

The electrical performance of a connection between two electrical contacts is generally measured by the contact electrical resistance between these two electrical contacts. The lower this electrical resistance, the better the contact. This electrical contact resistance depends on several factors such as the contact area and force, the resistivity of the materials of the electrical contacts, the temperature, etc.

Electrical contacts are generally made of copper or copper alloy, and often have a coating to ensure protection from the outside environment in order to protect the copper or copper alloy from corrosion while ensuring good electrical performance of the contacts. In the case of high-power electrical contacts, these coatings are usually gold or silver plating.

The connectors can be installed in environments with high vibration stresses and these vibrations then propagate to the interface between the electrical contacts. A relative movement can then be observed between them (corresponding to fretting), and the repetition of this movement tangential to the contact surface can cause contact wear. Fretting causes degradation of the protective coatings of the electrical contacts, which are then exposed to the external environment. The coppery substrate of the electrical contacts then undergoes corrosion and the debris from this wear oxidizes, which greatly impairs the electrical contact resistance and the service life of the electrical contacts. The increased contact resistance causes the contact to heat up locally, which increases its resistance even further. A thermal runaway phenomenon can then be observed, leading in the worst case to a fire outbreak.

In high power applications, high electrical currents can generate greater heating than that observed at low power contacts. This heating causes expansions of the various materials making up the connector, which allows greater relative movements of the electrical contacts. This heating also has consequences on the degradation of the electrical performance of the contact, since the oxidation phenomenon accelerates with temperature. In a high power context, the risk of fretting wear therefore no longer guarantees the reliability of the connectors and can become a major cause of damage if it is not taken into account.

Fretting is impacted by several factors that can change the behavior and wear of the contact, such as choice of materials, thickness of coatings, temperature, humidity, etc. The most impactful parameter of fretting wear of an electrical contact is the amplitude of movement of this electrical contact when it is subjected to a stress. Regardless of the type of coating used to protect the electrical contacts, the movement amplitude has a major influence on fretting wear and therefore on the service life of the contacts.

There are two main slip modes when two electrical contacts connected to each other are subjected to fretting stresses:
partial slip: this is a slip observed when the movement amplitude is low and below a threshold amplitude called “transition amplitude”. In this case, the contact is characterized by a so-called “stuck” zone located in the center of the interface between the two electrical contacts and surrounded by a so-called “slip” zone located at the periphery of this interface. At the “stuck” zone, no slip is observed and therefore the contact is not damaged. In this case, the metal-to-metal contact between the electrical contacts is maintained over time, and the service life of the contact can be considered infinite. On the other hand, the greater the movement amplitude, the smaller the area of the stuck zone, until it is zero when the moment amplitude is greater than or equal to the transition amplitude,
total slip: such slip occurs when the movement amplitude exceeds the transition amplitude. The slip is then extended to the entire contact surface and the deterioration leads to the increase in resistance as far as electrical failure of the contact.

The change in the endurance of a connection between two electrical contacts, i.e. the number of fretting cycles necessary to lead to the failure of this connection, as a function of the movement amplitude, can be modeled by a decreasing power law. The end-of-life criterion of a connection is based on a threshold value of the contact resistance not to be exceeded. For a given material, and for given connection conditions, there is a threshold value of the movement amplitude above which the endurance of the electrical contact decreases sharply.

Thus, the amplitude of the movement undergone by two electrical contacts connected to each other is a determining factor on the endurance, or service life, of the connection of these two electrical contacts, i.e. on the number of fretting cycles necessary to reach a contact resistance threshold value considered to be damage. The smaller the movement amplitude, the longer the service life of the contact. This movement amplitude is specific to each connection, as it depends on the design of the elements of this connection, which is a set of technical solutions based on parameters such as the materials used, the contact force applied, the contact surface, etc. It also depends on environmental parameters such as temperature.

To calculate the risk of wear by fretting of a given connector, it is necessary to know the amplitude of movement that this connector will undergo in service (for example in flight in the case of connectors used in an aircraft). It also depends on the design of the connector and the “freedom” of movement of the electrical contact(s) housed in the connector. The elements used to assess this amplitude are: the manufacturing tolerances of each of the parts making up the connector, the assembly clearances, the elastic deformations of the parts subject to vibration stresses, and the expansions of the materials as a function of the temperature of use. It is therefore very difficult to estimate this amplitude and to be able to guarantee the reliability of the contact, and therefore to assess the risk of fretting wear within a given connector.

There are different methods for assessing the reliability of a connector subjected to vibration stresses.

A first method consists in carrying out vibration tests according to the NF EN2591 test standard: these are the classic qualification tests of an electrical connector used in the aeronautical field. These tests consist in applying a vibration stress along 3 axes (6 directions) for a defined duration (typically 8 hours). Numerous checks are then carried out to ensure that the functional performance of the connector will not deteriorate. These checks are generally measurements of coupling/decoupling forces, plugging/unplugging forces of the electrical contact(s) of the connector, and resistance measurements of the electrical contact(s). These vibration tests are used to check that the connector is not damaged (particularly at the level of the connector casing) and that the connection is maintained when the connector is subjected to vibrations.

However, these tests are not long enough to estimate the durability of the connector over time. In addition, with this first method, the vibration tests vibrate the entire connector, but do not guarantee that a fretting movement will occur on the electrical contact(s) of the connector. This is because the electrical contacts can move in relative movement (phase opposition), which causes fretting, but can also move together (in phase), in which case no fretting movement occurs. This is due to the fact that the connector is made up of parts of different stiffness that can dampen the movements, resulting in the electrical contact(s) inside the connector not moving in the same way as the vibrating connector.

The connector also does not react in the same way depending on the temperature and the vibration stresses experienced, making it difficult to know if fretting occurs during the vibration test, and if so, it is not possible to know the amplitude of movement between the connected electrical contacts. This is because this movement amplitude seen by the electrical contacts depends on many factors, such as the assembly clearances of the parts making up the connector, the expansions of the parts due to temperature variations, and the elasticity of the materials subjected to vibration stresses.

Another method for assessing the behavior of a connector subjected to vibration stresses is to subject it to severe vibration tests: these are tests for which the vibration level and/or duration have been increased in order to increase the vibration stresses suffered by the connector. This increases the possibility/probability of creating fretting at the contact. However, for the same reasons as in the previous method, this type of test does not guarantee the occurrence of fretting and does not allow the severity of it to be known (in particular the movement amplitude).

When developing a high-power electrical connector intended for use on board an aircraft, several physical phenomena are taken into account, and the sizing of the resulting connector must ensure its reliability throughout the service life of the aircraft. Since fretting is also a sizing phenomenon for the connector (because it is a source of severe damage), it is important to evaluate it in order to take it into account when developing the connector.

This need to assess the service life of an electrical connection between two connectors, taking into account the risk of wear by fretting of the electrical contacts of these connectors, is also found in fields other than aeronautics, and more generally in the entire field of electrical connections.

### DISCLOSURE OF THE INVENTION

An aim of the present invention is to provide a method for evaluating the service life of an electrical connection between at least two connectors each having at least one electrical contact, taking into account the contact wear due to fretting.

For this purpose, the invention proposes a method for evaluating the service life of an electrical connection between at least two connectors each comprising at least one electrical contact housed in a casing, the casings of the two connectors being configured to be mechanically coupled to each other, comprising the following steps:
measuring the change in the contact electrical resistance between the electrical contacts alone, without the presence of another element of the connectors, as a function of a number of movements of the electrical contacts against one another and for several values of amplitude of movement of the electrical contacts against one another;
determining, from the measurements of the change in the electrical contact resistance between the electrical contacts, a function defining a maximum number of movements beyond which the electrical contact resistance between the electrical contacts exceeds a predefined maximum value representative of a degraded state of the connection, as a function of the movement amplitude;
measuring movement amplitudes, at each of the casings of the connector casings in which the electrical contacts are intended to be arranged, by subjecting the casings to mechanical stresses of different amplitude and frequency;
determining, from the measurements of movement amplitudes, dynamic transfer functions of the casings defining the movement amplitude of the electrical contacts as a function of the amplitude and frequency of the mechanical stresses applied to the casings;
determining, for given values of amplitude and frequency of mechanical stresses applied to the connectors, the service life of the connection between the connectors corresponding to the maximum number of movements beyond which the electrical contact resistance between the electrical contacts exceeds the predefined maximum value representative of a degraded state of the connection, this maximum number of movements being determined from the function defining the maximum number of movements beyond which the electrical contact resistance between the electrical contacts exceeds the predefined maximum value representative of a degraded state of the connection as a function of the movement amplitude, for an amplitude of movement of the electrical contacts against each other whose value is determined by the dynamic transfer functions of the connectors for the given values of amplitude and frequency of the mechanical stresses applied to the connectors.

The measurement of the change in the contact electrical resistance between the first and second electrical contacts alone implemented in this method corresponds to an evaluation of the endurance of the electrical contacts alone, in particular without connector casing, when they are subjected to fretting. This measurement makes it possible to know the endurance of the electrical connection formed between the electrical contacts as a function of the movement amplitude and the fretting conditions to which the electrical contacts are subjected.

During the method, a determination of the dynamic transfer functions from the casings to the electrical contacts is also implemented by an experimental modal analysis method applied to the connectors. Thus, it is possible to determine the movement amplitude of the electrical contacts when the connectors are subjected to external vibrations.

Finally, a comparison of these results is made to conclude on the qualitative reliability of the connection in a vibration environment. By comparing the amplitude of movement of the electrical contacts in the casings with the endurance curve at this same amplitude, it is possible to determine the change over time in the electrical contact resistance between the electrical contacts when they are housed in the connectors, for given mechanical stresses, and thus determine the service life of the connection formed between the connectors.

With this method, it becomes possible to know, according to the vibration stresses suffered by the connectors, whether the electrical contacts of these connectors are subjected to fretting or not. It is therefore possible to assess the service life of this connection as a function of the vibration stresses experienced, and therefore for example as a function of the zone where the connectors are installed in a transport vehicle such as an aircraft.

Based on the results obtained, it is possible to determine whether a possible resizing of the electrical contacts (coating thicknesses, contact pressure, etc.) and/or parts making up the connectors (selection of materials with regard to expansions, assembly clearances, etc.) makes sense.

The proposed method makes it possible to actually take into account the fretting phenomenon by intentionally causing it, in a controlled manner, during endurance tests on electrical contacts, unlike prior art solutions based on vibration tests during which fretting may not occur.

Determining the connector fretting endurance and the dynamic transfer functions of the connectors makes it possible to ultimately determine the reliability of the connection and its limits of use (in particular the possible installation areas thereof). This assessment of the service life of the connection may make it possible to identify areas for improvement of the design of the contacts and/or connectors if the service life determined is not satisfactory.

Advantageously, the method may be such that:
the change in the electrical contact resistance between the electrical contacts alone is measured for several frequency values of the movements undergone by the electrical contacts during these measurements, and the function defining the maximum number of movements beyond which the electrical contact resistance between the electrical contacts exceeds the predefined maximum value representative of a degraded state of the connection as a function of the movement amplitude is determined for these different frequency values of the movements undergone by the electrical contacts, and
a frequency of movement of the housings of the casings is also measured when the casings are subjected to mechanical stresses of different amplitude and frequency values, and the dynamic transfer functions of the casings are determined such that they also define frequency values of movement of the electrical contacts as a function of the amplitude and frequency values of the mechanical stresses, and
the maximum number of movements beyond which the electrical contact resistance between the electrical contacts exceeds the predefined maximum value representative of a degraded state of the connection is also determined for a frequency of movement of the electrical contacts against each other whose value is determined by the dynamic transfer functions of the casings for the given values of the amplitude and frequency of the mechanical stresses.

In the above configuration, the frequency with which the electrical contacts undergo fretting is also taken into account in the evaluation of the service life of the connection, thus improving the accuracy in this evaluation.

Advantageously, the method may be such that:
the measurements of the changes in the electrical contact resistance between the electrical contacts alone and the movement amplitudes of the housings of the casings are each carried out under various given environmental conditions for which the temperature and/or relative humidity and/or pressure values differ from each other, and
the function defining the maximum number of movements beyond which the electrical contact resistance between the electrical contacts exceeds the predefined maximum value representative of a degraded state of the connection according to the amplitude of movement and the dynamic transfer functions of the casings are determined for each of the different environmental conditions, and
the service life of the connection between the connectors is determined from the function defining the maximum number of movements beyond which the electrical contact resistance between the electrical contacts exceeds the predefined maximum value representative of a degraded state of the connection according to the amplitude of movement and the dynamic transfer functions of the casings obtained under identical given environmental conditions.

In the above configuration, the ambient temperature and/or relative humidity and/or pressure of the environment in which the connectors are located are taken into account in the assessment of the service life of the connection, thus improving the accuracy in this assessment.

In a particular configuration, the method may further include the steps of:
from the measurements of the change in the electrical contact resistance between the electrical contacts alone, determining a value of amplitude of movement of the electrical contacts against each other for which the electrical contact resistance between the electrical contacts remains lower than a predefined value representative of a start of degradation of the connection, and
determining, for the given amplitude and frequency values of the mechanical stresses applied to the connectors, an absence or not of degradation of the connection between the connectors by comparing the value of the amplitude of movement of the electrical contacts against each other for which the electrical contact resistance between the electrical contacts remains lower than the predefined value representative of a start of degradation of the connection with the value of the amplitude of movement of the electrical contacts against each other determined by the dynamic transfer functions of the casings for the given values of amplitude and frequency of mechanical stresses applied to the connectors.

In the particular configuration above, the method makes it possible to determine whether or not, under given operating conditions, the connection is affected by fretting.

Advantageously, the method may be such that:
the amplitudes of movement of the housings of the casings are measured by accelerometers and/or vibration sensors, and
the mechanical stresses to which the casings are subjected are applied by at least one impact hammer equipped with a head coupled to a force sensor configured to measure the amplitude and frequency of the applied mechanical stresses, or by a vibration generator, and
the accelerometers and/or vibration sensors, and the force sensor or the vibration generator, are electrically coupled to at least one spectrum analyzer determining the dynamic transfer functions of the casings.

One of the electrical contacts may correspond to a male electrical contact, and the other of the electrical contacts may correspond to a female electrical contact.

The different values of amplitude and frequency of the mechanical stresses can be representative of different locations in a transport vehicle. In this case, the transport vehicle may be an aircraft.

### BRIEF DESCRIPTION OF THE DRAWINGS

The present invention will be better understood upon reading the description of exemplary embodiments given for purely informational and in no way limiting purposes while referring to the appended drawings in which:

FIG. 1 shows an example embodiment of connectors wherein the service life of the connection with one another is evaluated by the method that is the object of the invention;

FIG. 2 shows schematically the steps of a method for evaluating the service life of an electrical connection that is the object of the present invention;

FIG. 3 shows schematically an example of a function defining a maximum number of movements beyond which the electrical contact resistance between the electrical contacts exceeds a predefined maximum value representative of a degraded state of the connection, according to the amplitude of movement, determined during a method for evaluating the service life of an electrical connection that is the object of the present invention.

Identical, similar or equivalent parts of the different figures described hereinafter bear the same numerical references so as to facilitate the transition from one figure to another.

The various parts shown in the drawings are not necessarily shown according to a uniform scale, to make the drawings more readable.

The various possibilities (alternatives and embodiments) must be understood as not being exclusive of each other and can be combined with each other.

### DETAILED DISCLOSURE OF PARTICULAR EMBODIMENTS

A method for evaluating the service life of an electrical connection between at least two connectors 100, 102 configured to be mechanically coupled to each other is described below.

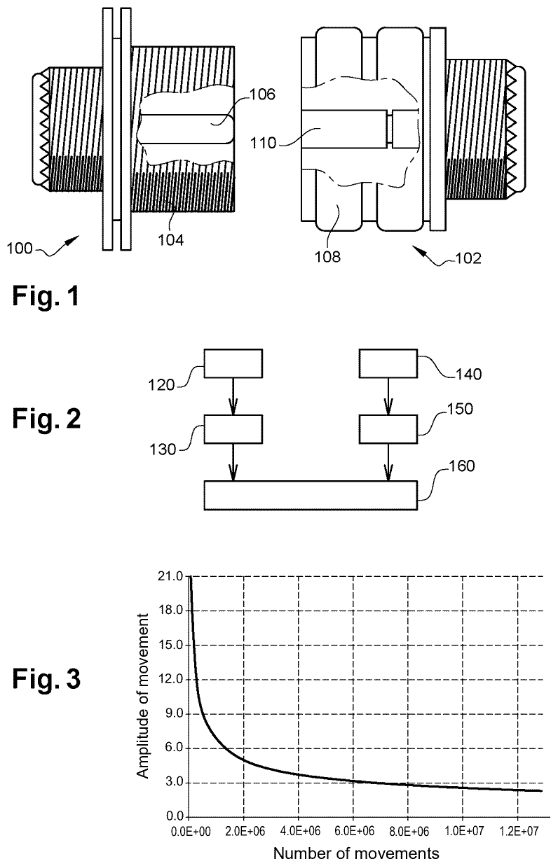

An example embodiment of the two connectors 100, 102 is visible in FIG. 1.

The connector 100, called the first connector 100, includes a first casing 104 in which at least one first electrical contact 106 is housed. In the exemplary embodiment shown in FIG. 1, the first connector 100 includes a first male-type electrical contact 106. The connector 102, called the second connector 102, includes a second casing 108 configured to be mechanically coupled to the first casing 104 and in which at least one second electrical contact 110 is housed. In the exemplary embodiment shown in FIG. 1, the second connector 102 includes a second electrical contact 110 of the female type and configured to be electrically connected to the first electrical contact 106.

The steps of the method for evaluating the service life of the electrical connection between the connectors 100, 102 when they are mechanically coupled to each other are described below and schematized in FIG. 2.

A step 120 of evaluating the endurance of the electrical contacts 106, 110 is implemented. This step 120 includes a measurement of the change in the contact electrical resistance between the electrical contacts 106, 110 alone, without the presence of another element of the connectors 100, 102 (in particular without the casings 104, 108), as a function of a number of movements of the electrical contacts 106, 110 against each other and for several movement amplitude values.

During these measurements, the electrical contacts 106, 110 are subjected to fretting by moving them, for example longitudinally, against each other, preferably by moving the first electrical contact 106 when the latter corresponds to a male electrical contact and holding in a fixed position the second electrical contact 110 when the latter corresponds to a female electrical contact.

These measurements are carried out for different values of amplitude of movement of the electrical contacts 106, 110 against each other, and for example using a milliohmmeter.

For each of the selected movement amplitude values, the change in the contact electrical resistance between the electrical contacts 106, 110 alone is measured until the measured contact electrical resistance value exceeds a predefined maximum value which depends on the specifications of the connectors 100, 102 and which is representative of a degraded state of the electrical connection between the electrical contacts 106, 110, or until a number of movements of the electrical contacts 106, 110 against each other carried out exceeds a maximum value, for example in the order of 10 million cycles, making it possible to consider that the electrical contacts 106, 110 are not degraded by these movements.

After the implementation of step 120, a step 130 is performed and consists in determining, from the measurements performed in step 120, a function defining a maximum number of movements beyond which the electrical contact resistance between the electrical contacts 106, 110 exceeds a predefined maximum value representative of a degraded state of the connection between the contacts 106, 110, depending on the amplitude of movement of the contacts 106, 110 against each other. An example of a curve representative of such a function is shown in FIG. 3, with the movement amplitude shown on the y-axis and the number of movements shown on the x-axis.

An experimental modal analysis of the connectors 100, 102 is then implemented. The objective of the experimental modal analysis is to determine the dynamic characteristics of the connectors 100, 102 and to identify the dynamic transfer functions from the casings 104, 108 to the electrical contacts 106, 110, i.e. the dynamic response of the connectors 100, 102 according to the mechanical stresses experienced.

During this analysis, known mechanical stresses are applied to the casings 104, 108 of the connectors 100, 102, and their response transmitted to the casings in which the electrical contacts 106, 110 are located is measured. For this purpose, during a step 140, the casings 104, 108 are subjected to mechanical stresses of different amplitude and frequency values, and the movement amplitudes, at each of the casings of the casings 104, 108 in which the electrical contacts 106, 110 are intended to be disposed, are measured.

Then, during a step 150, from the measurements of movement amplitudes of the casings carried out previously, dynamic transfer functions of the casings 104, 108 defining the movement amplitudes of the electrical contacts 106, 110 as a function of the amplitude and frequency of mechanical stresses applied to the casings 104, 108 are determined.

According to one embodiment, the movement amplitudes of the housings of the casings 104, 108 are measured by accelerometers and/or vibration sensors. Furthermore, the mechanical stresses to which the casings 104, 108 are subjected are for example applied by at least one dynamic impact hammer having a head coupled to a force sensor configured to measure the amplitude and frequency of the applied mechanical stresses, or by using a vibration generator. These different elements (accelerometers and/or vibration sensors, and the force sensor or the vibration generator) may be electrically coupled to at least one spectrum analyzer determining the dynamic transfer functions of the casings 104, 108.

Once the dynamic transfer functions of the casings 104, 108 have been determined, it is then possible to calculate the potential movement amplitude of the electrical contacts 106, 110 installed in the casings 104, 108 that corresponds to the result given by the dynamic transfer functions of the casings 104, 108 by applying the vibrational stresses that the connectors 100, 102 can undergo as input data. These vibration stresses are for example given according to installation conditions provided for the connectors 100, 102.

This is because, knowing that for a given stress, the electrical contacts 106, 110 housed in the casings 104, 108 will move in relative motion with a certain movement amplitude, and by knowing the endurance of the electrical contacts 106, 110 subjected to such movement amplitude, it is possible to conclude on the service life of the connection between the electrical contacts 106, 110 depending on this stress, and therefore depending for example on a zone where the connectors 100, 102 are installed in a vehicle (such as an aircraft) for which the stresses experienced therein are known.

Thus, during a step 160, for given values of amplitude and frequency of mechanical stresses applied to the connectors 100, 102, the service life of the connection between the connectors 100, 102 is determined. This service life corresponds to the maximum number of movements beyond which the electrical contact resistance between the electrical contacts 106, 110 exceeds the predefined maximum value representative of a degraded state of the connection. This maximum number of movements is determined from the function defining the maximum number of movements beyond which the electrical contact resistance between the electrical contacts 106, 110 exceeds the predefined maximum value representative of a degraded state of the connection as a function of the movement amplitude, for a movement amplitude of the electrical contacts 106, 110 against each other whose value is determined by the dynamic transfer functions of the connectors 100, 102 for the given values of amplitude and frequency of the mechanical stresses applied to the connectors 100, 102.

Advantageously, in addition to the movement amplitude of the electrical contacts 106, 110, it is also possible to take into consideration the frequency of fretting between the electrical contacts 106, 110. For this purpose, the method steps are implemented such that:
in step 120, the change in the contact electrical resistance between the electrical contacts 106, 110 alone can be measured for several frequency values of the movements undergone by the electrical contacts 106, 110 alone during these measurements;
in step 130, the function defining the maximum number of movements beyond which the electrical contact resistance between the electrical contacts 106, 110 exceeds a predefined maximum value representative of a degraded state of the connection according to the amplitude of movement is determined for these different frequency values of the movements undergone by the electrical contacts 106, 110;
in step 140, a frequency of movement of the housings of the casings 104, 108 is then also measured when the casings 104, 108 are subjected to mechanical stresses of different amplitude and frequency;
in step 150, the dynamic transfer functions of the casings 104, 108 are then determined such that they also define movement frequency values of the electrical contacts 106, 110 according to the amplitude and frequency values of the mechanical stresses;
finally, in step 160, the maximum number of movements beyond which the electrical contact resistance between the electrical contacts 106, 110 exceeds the predefined maximum value representative of a degraded state of the connection is also determined for a frequency of movement of the electrical contacts 106, 110 against each other whose value is determined by the dynamic transfer functions of the casings 104, 108 for the given values of the amplitude and frequency of mechanical stresses.

In the method described above, steps 120 to 150 are implemented under given environmental conditions. Advantageously, it is possible to repeat these steps by modifying these environmental conditions each time, i.e. by modifying each time the temperature and/or relative humidity values prevailing for the connectors 100, 102. In this case:
in steps 120 and 140, the measurements of the change in the contact electrical resistance between the electrical contacts 106, 110 alone and the movement amplitudes of the housings of the casings 104, 108 are each carried out under the various given environmental conditions;
in steps 130 and 150, the function defining the maximum number of movements beyond which the electrical contact resistance between the electrical contacts 106, 110 exceeds the predefined maximum value representative of a degraded state of the connection according to the amplitude of movement and the dynamic transfer functions of the casings 104, 108 are determined for each of the various environmental conditions;
in step 160, the service life of the connection between the connectors 100, 102 is determined from the function defining the maximum number of movements beyond which the electrical contact resistance between the electrical contacts 106, 110 exceeds the predefined maximum value representative of a degraded state of the connection according to the amplitude of movement and the dynamic transfer functions of the casings 104, 108 obtained under identical given environmental conditions.

In the method and the various variants above, the service life of the connection between the connectors 100, 102 is evaluated by determining the number of fretting cycles beyond which the electrical connection between them is degraded. When the mechanical stresses to which the connectors 100, 102 are subjected do not cause an amplitude of movement of the electrical contacts 106, 110 that is greater than the transition amplitude of these contacts, the service life of the electrical connection between the connectors 100, 102 can be considered infinite. The method described above may be implemented so as to determine whether the electrical connection between the connectors 100, 102, subjected to given mechanical stresses, has such a service life that can be considered infinite. For this purpose:
from the measurements of the change in the contact electrical resistance between the electrical contacts 106, 110 alone carried out in step 120, a value of the amplitude of movement of the electrical contacts 106, 110 against each other for which the contact electrical resistance between the electrical contacts 106, 110 remains less than a predefined value representative of a start of degradation of the connection between the electrical contacts 106, 110 is determined, and
for the given values of amplitude and frequency of the mechanical stresses applied to the connectors 100, 102, an absence or not of degradation of the connection between the connectors 100, 102 is determined by comparing the amplitude of movement of the electrical contacts 106, 110 against each other for which the contact electrical resistance between the electrical contacts 106, 110 remains lower than the predefined value representative of a start of degradation of the connection with the amplitude of movement of the electrical contacts 106, 110 against each other determined by the dynamic transfer functions of the casings for the given amplitude and frequency values of the mechanical stresses applied to the connectors 100, 102.

In the method and the various variants described above, steps 120 and 130 may be implemented before or after or simultaneously with steps 140 and 150.

What is claimed is:

1. A method for evaluating the service life of an electrical connection between at least two connectors each comprising at least one electrical contact housed in a casing the casings of the two connectors being configured to be mechanically coupled to each other, comprising the following steps:
measuring the change in the contact electrical resistance between the electrical contacts alone, without the presence of another element of the connectors as a function of a number of movements of the electrical contacts against each other and for several values of amplitude of movement of the electrical contacts against each other;
determining, from the measurements of the change in the electrical contact resistance between the electrical contacts a function defining a maximum number of movements beyond which the electrical contact resistance between the electrical contacts exceeds a predefined maximum value representative of a degraded state of the connection, as a function of the movement amplitude;
measuring movement amplitudes, at each of the casing casings of the connectors in which the electrical contacts are intended to be arranged, by subjecting the casings to mechanical stresses of different amplitude and frequency;
determining, from the measurements of movement amplitudes, dynamic transfer functions of the casings defining the amplitude of movement of the electrical contacts as a function of the amplitude and frequency of the mechanical stresses applied to the casings;
determining, for given values of amplitude and frequency of mechanical stresses applied to the connectors the service life of the connection between the connectors corresponding to the maximum number of movements beyond which the electrical contact resistance between the electrical contacts exceeds the predefined maximum value representative of a degraded state of the connection, this maximum number of movements being determined from the function defining the maximum number of movements beyond which the electrical contact resistance between the electrical contacts exceeds the predefined maximum value representative of a degraded state of the connection as a function of the movement amplitude, for an amplitude of movement of the electrical contacts against each other whose value is determined by the dynamic transfer functions of the connectors for the given values of amplitude and frequency of the mechanical stresses applied to the connectors.

2. The method according to claim 1, wherein:
the change in the electrical contact resistance between the electrical contacts alone is measured for several frequency values of the movements undergone by the electrical contacts during these measurements, and the function defining the maximum number of movements beyond which the electrical contact resistance between the electrical contacts exceeds the predefined maximum value representative of a degraded state of the connection as a function of the movement amplitude is determined for these different frequency values of the movements undergone by the electrical contacts, and
a frequency of movement of the housings of the casings is also measured when the casings are subjected to mechanical stresses of different amplitude and frequency values, and the dynamic transfer functions of the casings are determined such that they also define frequency values of movement of the electrical contacts according to the amplitude and frequency values of the mechanical stresses, and
the maximum number of movements beyond which the electrical contact resistance between the electrical contacts exceeds the predefined maximum value representative of a degraded state of the connection is also determined for a frequency of movement of the electrical contacts against each other whose value is determined by the dynamic transfer functions of the casings for the given values of the amplitude and frequency of the mechanical stresses.

3. The method according to claim 1, wherein:
the measurements of the change in the contact electrical resistance between the electrical contacts alone and the movement amplitudes of the casings of the casings are each carried out under different given environmental conditions for which the temperature and/or relative humidity and/or pressure values differ from each other, and the function defining the maximum number of movements beyond which the electrical contact resistance between the electrical contacts exceeds the predefined maximum value representative of a degraded state of the connection according to the amplitude of movement and the dynamic transfer functions of the casings are determined for each of the different environmental conditions, and
the service life of the connection between the connectors is determined from the function defining the maximum number of movements beyond which the electrical contact resistance between the electrical contacts exceeds the predefined maximum value representative of a degraded state of the connection according to the amplitude of movement and the dynamic transfer functions of the casings obtained under identical given environmental conditions.

4. The method according to claim 1, further comprising:
from the measurements of the change in the contact electrical resistance between the electrical contacts alone, determining an amplitude value of movement of the electrical contacts against each other for which the contact electrical resistance between the electrical contacts remains less than a predefined value representative of a start of degradation of the connection, and
determining, for the given values of amplitude and frequency of the mechanical stresses applied to the connectors an absence or not of degradation of the connection between the connectors by comparing the amplitude of movement of the electrical contacts against each other for which the contact electrical resistance between the electrical contacts remains less than the predefined value representative of a start of degradation of the connection with the amplitude of movement of the electrical contacts against each other determined by the dynamic transfer functions of the casings for the given values of amplitude and frequency of the mechanical stresses applied to the connectors.

5. The method according to preceding claim 1, wherein:
the movement amplitudes of the housings of the casings are measured by accelerometers and/or vibration sensors, and
the mechanical stresses to which the casings are subjected are applied by at least one impact hammer having a head coupled to a force sensor configured to measure the amplitude and frequency of the applied mechanical stresses, or by a vibration generator, and
the accelerometers and/or vibration sensors, and the force sensor or the vibration generator, are electrically coupled to at least one spectrum analyzer determining the dynamic transfer functions of the casings.

6. The method according to claim 1, wherein one of the electrical contacts corresponds to a male electrical contact, and the other of the electrical contacts corresponds to a female electrical contact.

7. The method according to claim 1, wherein the different values of amplitude and frequency of the mechanical stresses are representative of different locations in a transport vehicle.

8. The method of claim 7, wherein the transport vehicle is an aircraft.
